(19) United States
(12) Patent Application Publication
(10) Pub. No.: US 2026/0244820 A1
(43) Pub. Date: Aug. 20, 2026

(54) METHOD AND SYSTEM FOR PREDICTING THE LIFETIME OF LITHIUM ION BATTERIES PRODUCED WITH DIRECTLY RECYCLED ELECTRODE

(71) Applicant: CASE WESTERN RESERVE UNIVERSITY, Cleveland, OH (US)

(72) Inventors: Boman Su, Cleveland, OH (US); Chris Yingchun YUAN, Solon, OH (US)

(21) Appl. No.: 19/541,946

(22) Filed: Feb. 17, 2026

Related U.S. Application Data
(60) Provisional application No. 63/758,403, filed on Feb. 14, 2025.

(51) Int. Cl. G06F 30/20; H01M 10/54

(52) U.S. Cl. CPC G06F 30/20; H01M 10/54

(57) ABSTRACT

A computer-implemented method for predicting the remaining useful life of a directly recycled battery system, such as a directly recycled NMC-LMO battery system is described herein.

### RELATED APPLICATION

This application claims priority from U.S. Provisional Application No. 63/758,403, filed Feb. 14, 2025, the subject matter of which is incorporated herein by reference in its entirety.

### GOVERNMENT FUNDING

This invention was made with government support under 2101129 awarded by the National Science Foundation. The government has certain rights in the invention.

### BACKGROUND

Lithium-ion batteries (LIBs) have been widely used over the past decades in various fields, such as portable electronic devices, electric vehicles and energy storage systems. Nickel-manganese-cobalt (NMC) and lithium manganese oxide (LMO) are two of the most used types of cathode materials in LIBs. As reported, the global market share of NMC electrodes was around 60% in 2022. Meanwhile, LMO shared 16.2% of the market of cathode materials in 2019, with a prediction to grow by 13.8% in 2025. Compared to conventional recycling methods, direct recycling methods utilize a lithium source and high temperature to restore the lithium loss and recover the structural degradation of degraded cathode materials, which is much more cost-effective and environmentally friendly than conventional methods. The current industrial-scale LIB recycling typically deals with spent LIBs collected from various sources using different cathode materials. As the current industrial recycling processes can hardly separate mixed cathode materials into different components, the cathode materials directly recycled from spent LIBs are likely to be mixed cathode, e.g., mixed NMC-LMO cathode. The mixed NMC-LMO cathode has already been used in the lithium-ion battery cells in electric vehicles. It has been found that the degraded NMC-LMO cathode can be recovered with direct recycling methods to the same level of electrochemical performance as the pristine cathode materials. However, due to the long-term cycling in the first life of the batteries, the morphology and particle distribution of degraded cathode materials have been changed, which may influence the lifetime of the recycled materials. Thus, the long-term aging behavior of the directly recycled electrode remains unclear.

Currently, no existing modeling can successfully predict the lifespan of directly recycled electrodes. Nevertheless, lithium-ion batteries rely on mathematical models for accurate real-time management and controlling of degradation to ensure longevity. Therefore, an urgent need exists for a model-based approach to estimate their remaining useful life for the commercialization of directly recycled materials. Batteries incorporating directly recycled electrodes exhibit highly nonlinear behaviors, significantly influenced by external environmental factors. Electrochemical models are pivotal in this regard, as they solve complex equations governing charge and mass balances within the battery cell. This capability not only facilitates an in-depth exploration of degradation mechanisms but also enables the prediction of battery lifespan under diverse operating conditions.

Meanwhile, previous models of NMC-LMO electrode degradation focused on anode passivation layer formation and Mn dissolution. However, recent findings show that NMC suppresses Mn dissolution from LMO particles. Regarding NMC particles, degradation often involves phase transition from intact layered structures to deteriorated rock salt structures, causing active material loss, resistance increase, and changes in electrode properties. This transition is considered a primary degradation mechanism, particularly important for understanding NMC particle behavior in recycling processes.

### SUMMARY

This disclosure relates to a physics based method and electrochemical model to predict the lifetime of directly recycled electrodes of lithium ion batteries, such as a mixed nickel-manganese-cobalt/lithium manganese oxide (NMC-LMO) electrode, and particularly, to a computer-implemented method for predicting the remaining useful life of a directly recycled battery system, such as a directly recycled NMC-LMO battery system. The method includes receiving by an electrochemical model: data pertaining to components and configuration of the directly recycled battery system; data pertaining to governing equations that describe electrochemical performance of the directly recycled battery system; and data pertaining degradation mechanisms affecting the battery's performance over time. Electrochemical model parameters are then defined and adjusted at least in part based on the received data to accurately reflect the battery electrochemical performance. The electrochemical model can be calibrated by comparing its predictions with experimental and historical data from real-world batteries with directly recycled electrodes. Predictive analytics and uncertainty quantification are performed by using the calibrated electrochemical model to simulate and analyze the remaining useful life of the batteries under different operating conditions. The predicted remaining useful life of the directly recycled battery system is transmitted to a presentation on a user interface of a computing device or is further processed by another computer device.

In some embodiments, the directly recycled battery system includes an anode material selected from lithium metal for half-cell and graphite for full-cell, a cathode material comprising a directly recycled mixed electrode, such as an NMC-LMO mixed electrode, and an electrolyte comprising a lithium-ion conducting electrolyte.

In some embodiments, the governing equations for the battery system include mass balance equations, charge balance equations, and electrochemical kinetics equations. The electrochemical kinetics equations include, for example, a modified Butler-Volmer equation that models a first electrode intercalation, such as NMC electrode intercalation, a second electrode intercalation, such as LMO electrode intercalation, and side reactions occurring within the battery system.

In some embodiments, degradation mechanisms for the battery system can include layer-rock salt phase transformations in NMC, resulting in anode passivation layer formation and resistance growth, as well as Mn dissolution in LMO, which is mitigated by the presence of NMC. The impact of layer-rock salt phase transformations in NMC on degradation modes can include the loss of active material, the loss of lithium inventory, resistance growth, and changes in thermodynamic properties.

In some embodiments, the electrochemical model is utilized to predict the impact of various degradation mechanisms on the capacity loss behaviors of the directly recycled battery system, such as a directly recycled NMC-LMO battery system.

In some embodiments, the governing equations incorporated with degradation mechanisms are solved numerically using finite element analysis to simulate the electrochemical performance of the directly recycled battery system, such as a directly recycled NMC-LMO battery system.

Ins some embodiments, the electrochemical model parameters that are adjusted include aging-induced changes in material properties, such as equilibrium potential changes, initial passivation layer thickness, degradation current density and other material properties, such as material properties of NMC and LMO.

In some embodiments, the experimental data required for calibration of directly recycled battery materials can include voltage behavior, rate capability, and cycling loss. The calibration can involve adjusting model parameters based on experimental data to enhance the accuracy of predictive analytics for the battery system.

In some embodiments, predictive analytics are used to forecast the remaining useful life based on various initial capacities of the directly recycled electrode.

In some embodiments, uncertainty quantification can include analyzing the impact of voltage range, applied current, and operating temperature on the remaining useful life of the batteries.

Other embodiments described herein relate to a system for implementing the computer-implemented method described herein. The system can include a processor configured to execute the predictive analytics, a memory device for storing the data corresponding to remaining useful life of a recycled battery system, and a user interface of a computing device for inputting operational conditions and analyzing predictive outputs and presenting the predicted remaining useful life of the directly recycled battery system. The data can include, for example, components and configurations of recycled battery system, governing equations that describe the electrochemical performance of the battery system, and degradation mechanisms affecting the battery's performance over time.

In some embodiments, the system can further include a data acquisition module for collecting experimental data from aged batteries for use in a machine learning model calibration.

In some embodiments, the processor is further configured to receive the electrochemical model from a computing system, such as a cloud-based computing system.

Other embodiments described herein relate to a non-transitory computer readable medium storing a computer readable program that when executed causes a processor to receive, by an electrochemical model, data corresponding to remaining useful life of a recycled battery system. The data can include components and configurations of recycled battery system, governing equations that describe the electrochemical performance of the battery system, and degradation mechanisms affecting the battery's performance over time. Electrochemical model parameters are defined and adjusted to reflect the battery's electrical performance. The electrochemical model is calibrated by comparing predictions with experimental or a historical record of the data from real-world batteries with directly recycled electrodes. Predictive and uncertainty quantifications are then performed by using the calibrated model to simulate and analyze the remaining lifetime of the recycled battery system under different operating conditions.

### BRIEF DESCRIPTION OF THE DRAWINGS

FIG. 1 illustrates a flow chart of a method for predicting the lifetime of a lithium ion battery produced with a directly recycled electrode.

FIG. 2 illustrates an expanded flowchart of the proposed method of FIG. 1.

FIG. 3 illustrates experimental data and simulated results comparison of the directly recycled electrode cycling loss behavior with O.5C applied current rate under the voltage window range from 2.8Vto4.2V.

FIG. 4 illustrates remaining useful life computation for 0.5C applied current rate under the voltage window range from 2.8V to 4.2V.

FIGS. 5(A-H) illustrates the extraction processes of degraded NMC-LMO from spent lithium-ion batteries: A) Spent lithium-ion pouch cells, B) The cathode with a residual separator on the surface, C) The cathode after cleaning with acetone, D) The stirring process, E) The centrifuge process, F) The vacuum drying process, G) The vacuum filtration process, H) The pure degraded mixed NMC-LMO cathode material.

FIGS. 6A-B is a schematic diagram of the NMC-LMO A) full cell and B) half-cell.

FIG. 7 illustrates the equilibrium potential (φ_{eq}) of the pristine NMC and the modified φ_{eq} of the directly recycled NMC cathode.

FIG. 8 Pristine NMC-LMO-graphite full cell discharge voltage curves comparison at 1C, 3C, 5C, and 7C current rates. Experimental data reproduced from Jung et al.

FIGS. 9(A-B) illustrates validation of the electrochemical performance of the directly recycled NMC-LMO half-cell before cycling a) 0.5C voltage curve with and without φ_{eq} revision b) Rate capability comparison at 0.1C, 0.2C, 0.5C, 1C, 2C current rates.

FIGS. 10(A-B) illustrate validation of the cycling performance of the directly recycled NMC-LMO half-cell A) Discharge voltage curve at the 6th 300th and 500th cycle B) Capacity loss and the growth of passivation layer thickness with respect to cycle number.

FIGS. 11(A-B) illustrate voltage A) behavior simulation under different combination of degradation modes. B) Percentage of capacity and power loss caused by each degradation mode.

FIG. 12 illustrates rate capability of the fresh and aged direct recycled NMC-LMO electrode.

### DETAILED DESCRIPTION

The terms “transmit,” “receive,” and “communicate,” as well as derivatives thereof, encompass both direct and indirect communication. The terms “transmit,” “receive,” and “communicate,” as well as derivatives thereof, encompass both communication with remote systems and communication within a system, including reading and writing to different portions of a memory device.

The terms “include” and “comprise,” as well as derivatives thereof, mean inclusion without limitation.

The term “or” is inclusive, meaning or.

The phrase “associated with,” as well as derivatives thereof, means to include, be included within, interconnect with, contain, be contained within, connect to or with, couple to or with, be communicable with, cooperate with, interleave, juxtapose, be proximate to, be bound to or with, have, have a property of, have a relationship to or with, or the like.

The term “controller” means any device, system or part thereof that controls at least one operation. Such a controller may be implemented in hardware or a combination of hardware and software or firmware.

The functionality associated with any particular controller may be centralized or distributed, whether locally or remotely.

The phrase “at least one of,” when used with a list of items, means that different combinations of one or more of the listed items may be used, and only one item in the list may be needed. For example, “at least one of: A, B, and C” includes any of the following combinations: A, B, C, A and B, A and C, B and C, and A and B and C.

Moreover, various functions described below can be implemented or supported by one or more computer programs, each of which is formed from computer readable program code and embodied in a computer readable storage medium.

The terms “application” and “program” refer to one or more computer programs, software components, sets of instructions, procedures, functions, objects, classes, instances, related data, or a portion thereof adapted for implementation in a suitable computer readable program code.

The phrase “computer readable program code” includes any type of computer code, including source code, object code, and executable code.

The phrase “computer readable storage medium” includes any type of medium capable of being accessed by a computer, such as read only memory (ROM), random access memory (RAM), a hard disk drive, a compact disc (CD), a digital video disc (DVD), solid state drive (SSD), or any other type of memory.

A “non-transitory” computer readable storage medium excludes wired, wireless, optical, or other communication links that transport transitory electrical or other signals. A non-transitory computer readable storage medium includes media where data can be permanently stored and media where data can be stored and later overwritten, such as a rewritable optical disc or an erasable memory device.

The term “user profile” refers to a “user battery usage profile” throughout this disclosure.

This disclosure describes a physics-based method and an electrochemical model for real-time prediction of the lifespan of directly recycled lithium-ion electrodes, such as directly recycled mixed NMC-LMO electrodes. The electrochemical model incorporates kinetics of the electrode and side reactions. Specifically, the degradation behavior of NMC-LMO electrode was examined for the first time using an electrochemical model considering the effect of NMC structural reconstruction. A modification of the equilibrium potential of the directly recycled cathode material is applied to capture the thermodynamic behavior change of the directly recycled electrode during its first life. Various degradation modes, including resistance increase on the anode and the cathode, loss of active material and loss of recyclable lithium, have been examined and incorporated into the model. The model is validated with lab-generated experimental data on directly recycled mixed NMC-LMO electrode half cells, including voltage behaviors, rate capability, and cycling performances. The results indicate that loss of recyclable lithium dominates the degradation behavior of the directly recycled mixed NMC-LMO electrode among all the degradation modes being considered, which accounts for 78.9% and 71.3% of the total capacity and power loss, respectively. In addition, it was found that after 500 cycles, the directly recycled mixed NMC-LMO electrode can deliver 90% of its original capacity with 0.1C testing rate, compared to only 64% of capacity retention at 1C testing rate. The results demonstrate that the directly recycled electrode can maintain high-quality performance comparable to pristine materials in low-current applications. The model can be integrated into battery management systems (BMS), promising enhanced operational efficiency and extended battery longevity, marking a significant advancement in sustainable battery technology.

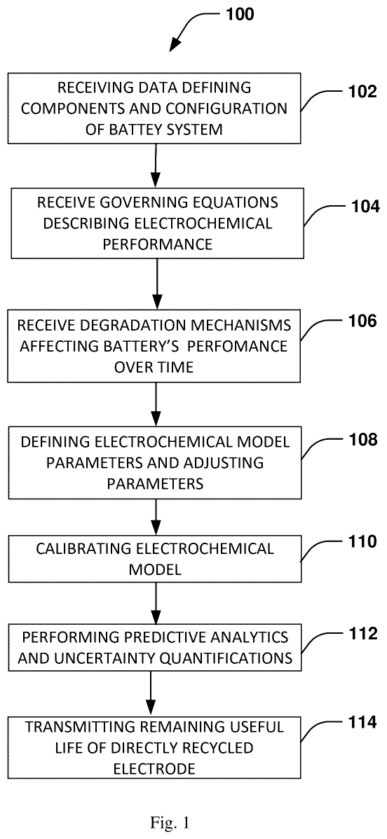

FIG. 1 illustrates example operations of a method 100 for using an electrochemical model to predict a remaining useful life of directly recycled lithium-ion electrodes, such as directly recycled mixed NMC-LMO electrodes according to certain embodiments of this disclosure. The method 100 is performed by processing logic that may include hardware (circuitry, dedicated logic, etc.), software (such as is run on a computer system or specialized dedicated machine), or a combination of both. The method 100 or each of their individual functions, routines, subroutines, or operations may be performed by one or more processors of a computing device, such as a server executing an artificial intelligence engine. In certain implementations, the method 100 may be performed by a single processing thread. Alternatively, the method 100 may be performed by two or more processing threads, each thread implementing one or more individual functions, routines, subroutines, or operations of the methods. In some embodiments, one or more accelerators may be used to increase the performance of a processing device by offloading various functions, routines, subroutines, or operations from the processing device.

For simplicity of explanation, the method 100 is depicted and described as a series of operations. However, operations in accordance with this disclosure can occur in various orders or concurrently, and with other operations not presented and described herein. For example, the operations depicted in the method 100 may occur in combination with any other operation of any other method disclosed herein. Furthermore, not all illustrated operations may be required to implement the method 100 in accordance with the disclosed subject matter. In addition, those skilled in the art will understand and appreciate that the method 100 could alternatively be represented as a series of interrelated states via a state diagram or events.

In some embodiments, one or more machine learning models may be generated and trained by an artificial intelligence engine and/or the training engine to perform one or more of the operations of the methods described herein. For example, to perform the one or more operations, the processing device may execute one or more machine learning models. In some embodiments, the one or more machine learning models may be iteratively retrained to select different features capable of enabling optimization of output. The features that may be modified may include a number of nodes included in each layer of the machine learning models, an objective function executed at each node, a number of layers, various weights associated with outputs of each node, and the like.

In the method 100, at 102, a processing device may receive data pertaining to components and configuration of the directly recycled battery system. The directly recycled battery system include an anode material selected from lithium metal for half-cell and graphite for full-cell, a cathode material comprising a directly recycled mixed electrode, such as an NMC-LMO mixed electrode, and an electrolyte comprising a lithium-ion conducting electrolyte.

At 104, processing device may receive data pertaining governing equations that describe electrochemical performance of the directly recycled battery system. In some embodiments, the governing equations for the battery system include mass balance equations, charge balance equations, and electrochemical kinetics equations. The electrochemical kinetics equations include, for example, a modified Butler-Volmer equation that models a first electrode intercalation, such as NMC electrode intercalation, a second electrode intercalation, such as LMO electrode intercalation, and side reactions occurring within the battery system.

At 106, the processing device may receive data pertaining degradation mechanisms affecting the battery's performance over time. The degradation mechanisms for the battery system can include layer-rock salt phase transformations in NMC, resulting in anode passivation layer formation and resistance growth, as well as Mn dissolution in LMO, which is mitigated by the presence of NMC. The impact of layer-rock salt phase transformations in NMC on degradation modes can include the loss of active material, the loss of lithium inventory, resistance growth, and changes in thermodynamic properties.

In some embodiments, the governing equations incorporated with degradation mechanisms are solved numerically using finite element analysis to simulate the electrochemical performance of the directly recycled battery system, such as a directly recycled NMC-LMO battery system.

At 108, electrochemical model parameters are then defined and adjusted at least in part based on the received data to accurately reflect the battery electrochemical performance. The adjustable parameters include aging-induced changes in material properties, such as equilibrium potential changes, initial passivation layer thickness, degradation current density and other material properties, such as material properties of NMC and LMO.

At 110, the electrochemical model can be calibrated by comparing its predictions with experimental and historical data from real-world batteries with directly recycled electrodes. The experimental data required for calibration of directly recycled battery materials can include voltage behavior, rate capability, and cycling loss. The calibration can involve adjusting model parameters based on experimental data to enhance the accuracy of predictive analytics for the battery system.

At 112, predictive analytics and uncertainty quantification are performed by using the calibrated electrochemical model to simulate and analyze the remaining useful life of the batteries under different operating conditions. The predictive analytics can be used to forecast the remaining useful life based on various initial capacities of the directly recycled electrode. The uncertainty quantification can include analyzing the impact of voltage range, applied current, and operating temperature on the remaining useful life of the batteries.

In some embodiments, the electrochemical model may be used with a machine learning model. The machine learning model may be configured using the parameters and may use at least the one or more properties to predict the remaining useful life of the directly recycled battery. A computing system can be used to train the machine learning model by optimizing one or more parameters in an iterative process. Further, a computing device or system may extract one or more features from at received data. Once the machine learning model is configured based on the parameters, real-time data and/or battery profile is received at the processing device, the electrochemical model can predict the remaining useful life directly recycled electrode in real-time based on the real-time data.

In some embodiments, the electrochemical model is utilized to predict the impact of various degradation mechanisms on the capacity loss behaviors of the directly recycled battery system, such as a directly recycled NMC-LMO battery system.

At 114, the processing device may transmit the remaining useful life of directly recycled electrode for presentation on a user interface of a computing device. In some embodiments, the processing device may transmit the remaining useful life of directly recycled electrode to be used before the battery system reaches an end of life state. In some embodiments, the computing device may be associated with a user.

In some embodiments, based on the remaining useful life, the processing device may perform a preventative action. The preventative action may include causing an operating parameter of the battery system to change to consume less charge or service the battery, issue an advisory message on use of the battery pack, notify a service manager of the state of the battery, or some combination thereof.

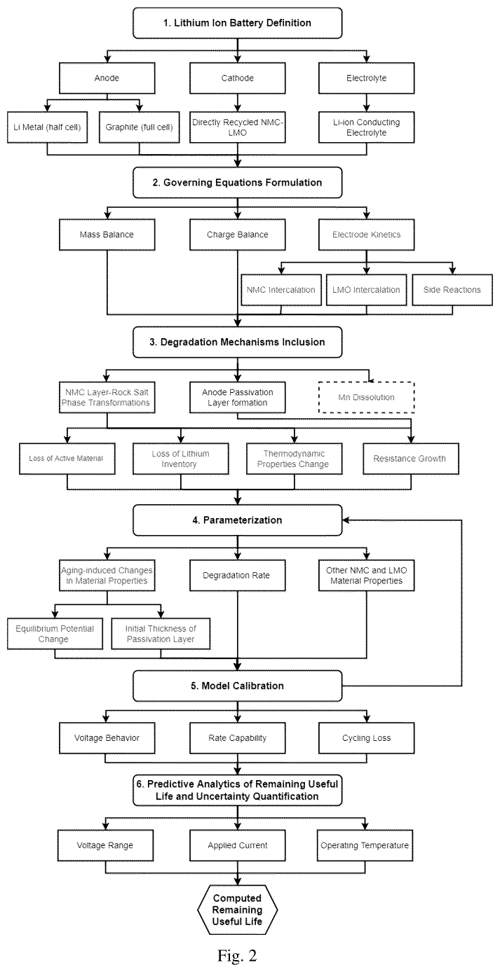

FIG. 2 illustrates a flow chart of example operations of a method for using an electrochemical model to predict a remaining useful life of directly recycled mixed NMC-LMO electrodes in accordance with another embodiment. The method begins with defining the lithium ion battery components, including anode materials (Lithium metal or graphite), and cathode materials (directly recycled NMC-LMO mixed electrodes), all immersed in a lithium ion conducting electrolyte. Formulation of governing equations follows, encompassing mass and charge balance and electrochemical kinetics, which are described with a modified Butler-Volmer equation. Specifically, the total current density in the electrochemical model is defined as a combination of lithium ions intercalation in NMC and LMO, together with the side reaction current density of phase transformation on the cathode.

Degradation mechanisms are then incorporated, addressing phase transformations in NMC and anode passivation layers. Note that Mn dissolution in LMO is ignored as the presence of NMC is found to be able to suppress this reaction. Four degradation modes resulting from phase transformations in NMC and anode passivation layer formation are coupled in this model, i.e., resistance increase on the anode, resistance increase on the cathode, loss of active material and loss of recyclable lithium. The thermodynamic property change of NMC due to aging is also considered by modifying the equilibrium potential of NMC.

Parameters influencing battery behavior are identified and quantified, including aging-induced changes, degradation rate, and material properties of NMC and LMO. Aging-induced changes specifically involve adjustments to the equilibrium potential of the electrode and the initial thickness of the passivation layer. For model calibration, these aging-induced parameters are fine-tuned by aligning simulation results with the experimental data of voltage curves, rate capability, and cycling losses from NMC-LMO lab-assembled CR2032 coin cells.

The electrochemical model is then employed to predict relationships between cycle number and remaining capacity, facilitating the computation of the remaining useful life (RUL). In this computation for directly recycled electrodes, the end-of-life threshold is defined as 70% of the original capacity. The RUL can be expressed as

$$RUL = C ( Qin ) - C ( Qen ) \qquad ( 2 )$$

where C(Q) is the computed cycle number corresponding to the capacity Q, subscribes in and en represents the initial and end-of-life state of the battery.

Uncertainties in RUL predictions are assessed by utilizing the model to forecast battery performance under varying environmental and operational conditions, such as temperature, voltage range, and applied current. Leveraging all computational outcomes, RUL can be formulated as a function of remaining capacity, applied current, and voltage range. This formulation can then be integrated into the BMS.

$$RUL = f ( Qin , V , I , T ) \qquad ( 3 )$$

where V stands for the applied voltage range, I refers to the applied current. T represents the operating temperature.

In real-time RUL computation, the model can undergo continuous refinement by incorporating feedback from test data to update its parameters using, for example, a machine learning model. This method can be extended to estimate RUL other electrode materials, such as LFP, LCO, etc., provided that their specific degradation mechanisms are thoroughly examined and integrated into the model.

The model is validated with the experimental data of voltage behavior, rate capability and cycling loss of a lab-generated coin cell made with a directly recycled NMC-LMO electrode. More details of the validation can be found in the Example.

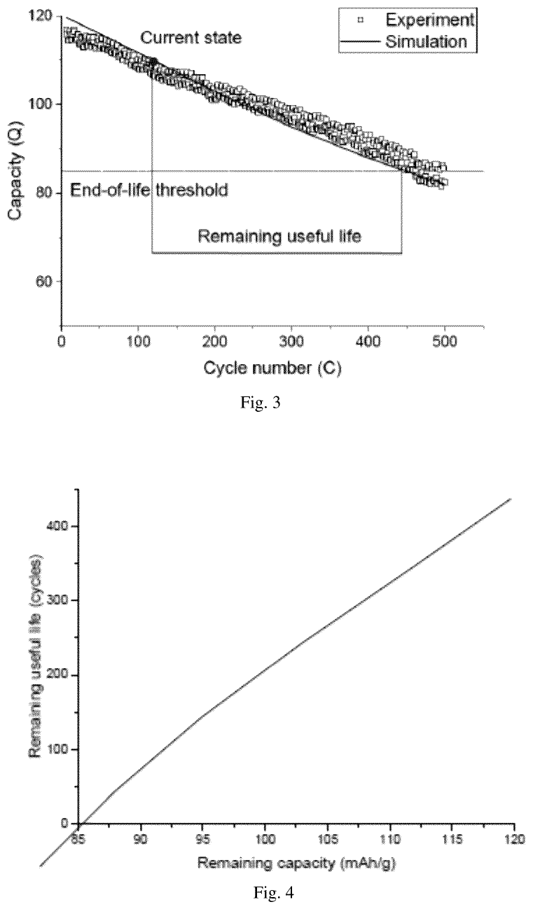

FIG. 3 shows the computation result of the cycling loss compared with the experimental data, demonstrating that the electrochemical model can reasonably predict the relation between remaining capacity and the cycle number of the directly recycled NMC-LMO electrode.

FIG. 4 shows the remaining useful life of the directly recycled NMC-LMO electrode under different initial capacities, with a voltage range of 2.8V to 4.2V and an applied CUITent rate of 0.5C. It can be seen that the battery will reach its end-of-life when the capacity reaches around 85 mAh/g, which is 70% of the original capacity. The proposed method can successfully estimate the remaining useful life of the directly recycled NMC-LMO electrode.

### Example

In this example, an electrochemical model coupled with the shrinkage-core model was developed to capture the voltage behavior, rate capability and cycling performance of the mixed NMC-LMO electrode recovered from spent lithium ion batteries through direct recycling methods. Particularly, the degradation behavior of NMC-LMO was investigated using an electrochemical model that considers the effect of NMC structural reconstruction. A modification of the equilibrium potential of the directly recycled cathode material is implemented to account for the thermodynamic changes in the recycled electrode during its first life. With the proposed model, the capacity and power loss caused by degradation modes, such as loss of recyclable lithium, loss of active material and resistance increase, are quantified separately. Finally, suggestions are given to optimize the behavior of the cathode recovered from direct recycling methods for future applications. This is the first attempt to depict the electrochemical performance of a mixed NMC-LMO cathode recovered by direct recycling methods through an electrochemical model. This Example aims to expand the understanding of the degradation behaviors of mixed cathodes directly recycled from spent lithium ion batteries and to provide useful suggestions for the future applications of these mixed electrodes.

To generate experimental data for model validations, half cells were assembled with mixed NMC-LMO electrodes recovered from spent lithium ion batteries through direct recycling processes. The voltage behaviors, rate capability and cycling performances are tested for the assembled half cells.

### Regeneration of the Degraded NMC-LMO Cathode Materials

The spent lithium ion pouch cells retrieved from actual electric vehicles were disassembled after fully discharged to 2.6 V. The separated cathode was soaked in dimethyl carbonate (DMC) for 10 hours and then cleaned with acetone to remove the residual electrolyte and separators. Next, the electrodes were soaked and stirred in excessive N-Methyl-2-pyrrolidone (NMP) at 60° C. for ten hours and then centrifuged to remove the binders and carbon blacks. The obtained materials were dissolved in the 0.1M NaOH solution to remove the aluminum and then filtered and washed with distilled water several times to remove the impurities in the vacuum filtration system. After two hours of drying in the vacuum oven at 120° C., the degraded cathode material was ready to be relithiated. The extraction processes of degraded NMC-LMO from spent lithium-ion batteries are shown in FIG. 5. The degraded NMC-LMO cathode material mixed with excessive LiNO₃ served as the lithium source was grounded at 20 rpm for 10 minutes, and then preheated at 150° C. for two hours and sintered at 300° C. for ten hours in the furnace to regenerate the degraded NMC-LMO cathode. Then, the recycled cathode material was grounded at 50 rpm for five minutes to avoid agglomeration and reduce the particle size. Finally, the regenerated NMC-LMO cathode was cleaned with distilled water in the vacuum filtration system to remove the residual lithium salts and dried in the vacuum oven at 120° C. for two hours.

### Coin Cell Assembly and Electrochemical Performance Tests

The recycled NMC-LMO prepared above was fabricated into the cathode, and lithium foil was used as the counter electrode. The electrolyte used was 1.2M LiPF₆ in ethylene carbonate (EC): ethyl methyl carbonate (EMC): DMC (1:1:1 wt %). The half cells were assembled as CR2032 coin cells. All the tests were conducted with the Neware Battery Tester, and the lab temperature was around 25° C.

Each cell underwent five formation cycles with a charging and discharging rate of 0.1C, and all subsequent cycles were conducted at 0.5C under the voltage range from 2.8 to 4.2V. The rate capability test was conducted under the current rate of 0.1C, 0.2C, 0.5C, 1C, 2C, 5C, and 0.1C, including three sequential steps: (1) charge at a constant current of 0.5C until the cutoff voltage of 4.2V. (2) charge at a constant voltage of 4.2V until the cutoff current of 0.02C. (3) discharge at a desired current rate (0.1C, 0.2C, 0.5C, 1C, 2C, 5C) until the cutoff voltage of 2.7V; The steps mentioned above are repeated five times for each current rate. The results of the rate capability are given in step (3).

To obtain the specific capacity and cycling performance of the directly recycled electrode, the half cells were tested for 500 cycles following three steps: (1) charge at a constant current of 0.5C until the cutoff voltage of 4.2V. (2) charge at a constant voltage of 4.2V until the cutoff current of 0.02C. (3) discharge at a 0.5C constant current rate until the cutoff voltage of 2.8V. The results of the 0.5C discharge curves and cycling capacity loss are given in step (3). The steps mentioned above are repeated 500 times.

### Model Description

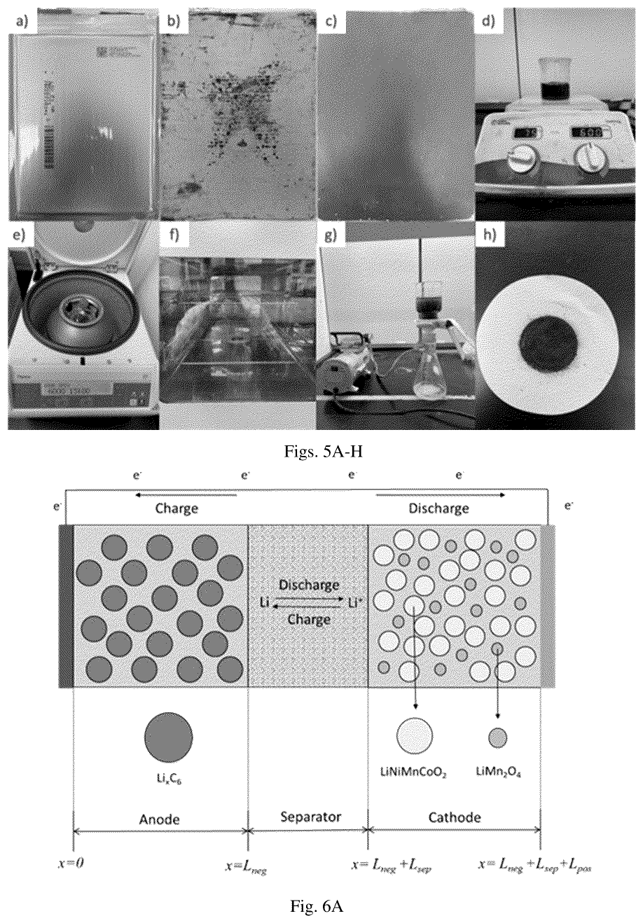

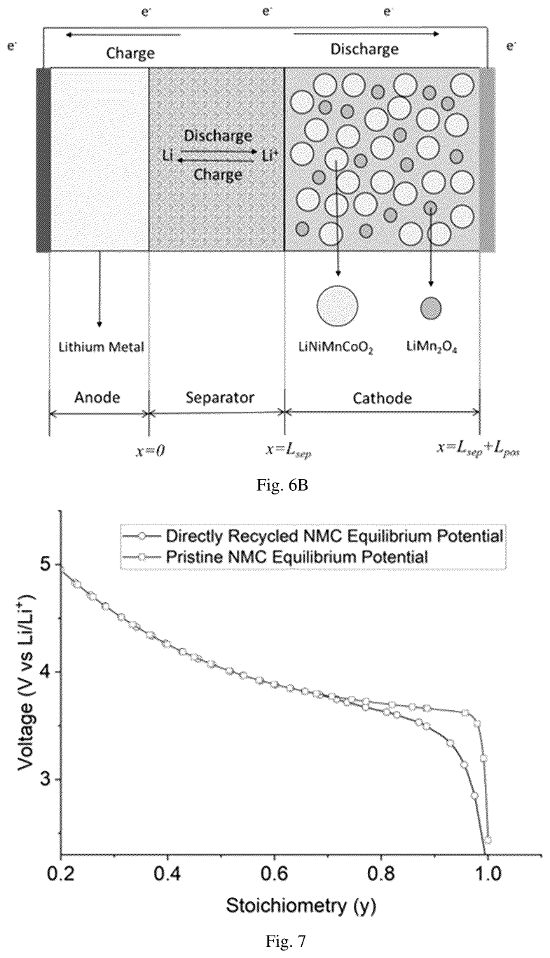

An electrochemical model is developed to simulate the performance of the pristine NMC-LMO full-cell and the directly recycled NMC-LMO half-cell. The full-cell model describes an NMC-LMO full-cell with a graphite anode, while the half-cell model is based on the lab-assembled CR2032 coin cell. Schematic diagrams of the full-cell and half-cell systems are illustrated in FIGS. 6A and 6B, respectively. Based on available experimental studies on the structural changes of NMC and LMO electrodes, several assumptions have been made for this model: (1) the degradation behavior of NMC electrode attributed to structural reconstruction, leading to the formation of a passivation layer on the particle surface and the thermodynamic property change of the electrode. (2) Since the LMO electrode is relatively stable with the presence of NMC, side reactions on the LMO electrode are ignored (3) Since the microstructural changes only happened on the passivation layer on the surface of the electrode, the equilibrium potential (φeq) of NMC remains unchanged in the bulk of NMC. (4) The adjustment needs to be made on φeq of the cathode during charge is minor. This is because thermodynamic properties can remain stable during deintercalation (charging) due to the layered crystal structure facilitating minimal structural change, while intercalation (discharging) induces greater strain and instability, altering these properties. Additional details of the governing equations, parameters and simulation steps are described below.

### Electrode Kinetics

Two sets of simulations are conducted: 1) A simulation of an NMC-LMO-Graphite full cell using a pristine NMC-LMO electrode. 2) A simulation of an NMC-LMO half cell utilizing a directly recycled NMC-LMO electrode. The full cell mathematical model of the lithiation and de-lithiation process on the electrode shown in FIG. 6A. The electrode kinetics of the half cell will be described in detail. As shown in FIG. 6B, the half cell consists of a lithium metal anode, a separator, and a mixed NMC-LMO cathode. During discharge, lithium ions generated by lithium particle oxidations on the anode pass through the electrolyte and separator and intercalate into the cathode material. During charge, the lithium ions deintercalate from the cathode and reduce back to lithium metal particles at the anode.

### Electrode Kinetics on the Anode

On the anode side, the current density comes from the oxidation and reduction of lithium inventory on the surface of the lithium metal and the formation of the passivation layer. The dead lithium accumulation at the lithium metal anode introduces a tortuous pathway for transporting lithium ions, which can be seen as a passivation layer with a large resistance. The total current density on the anode can be described using the following equation:

$${i}_{total , a} = {i}_{a , 0} ( {e}^{\frac{{α}_{a} F}{R T} {η}_{a}} - {e}^{\frac{{α}_{c} F}{R T} {η}_{a}} ) + {i}_{side , a} \qquad ( 1 )$$

where i_{α,0} represents the exchange current density of the anode lithium oxidation, i_{side,α} is the side reaction current density leading to the resistance increase on the anode, F indicates the Faraday's constant, αₐ/α_{c} are the charge transfer coefficients of the anodic/cathodic reaction, R represents the universal gas constant, Tis the battery operation temperature, and η_{α} represents the overpotential of the lithium metal oxidation/lithium ions reduction on the anode, given as:

$${η}_{a} = {ϕ}_{s} - {ϕ}_{l} - {ϕ}_{eq , a} - {R}_{pass , a} {i}_{total , a} \qquad ( 2 )$$

where, φₛ is the potential of the electrode, φₗ is the potential of the electrolyte, φ_{eq,α} is the equilibrium potential of the Li metal anode, which is equal to 0V theoretically and R_{pass,α} is the resistance of the passivation layer on the anode.

The current density of lithium accumulation on the anode can be described as:

$${i}_{side , a} = - {i}_{side , a , 0} {e}^{\frac{- {α}_{c , side , a} {n}_{side , a} F}{R T} {η}_{side , a}} \qquad ( 3 )$$

where i_{side,α} indicates the side reaction current density of the lithium accumulation, α_{c,side,α} is the cathodic charge transfer coefficient of lithium accumulation on the anode, i_{side,α,0} is the exchange current density of passivation layer formation on the anode. η_{side,α} is the mole number of lithium inventory loss to form one mole of the passivation layer. η_{side,α} is the overpotential of the passivation layer formation on the anode, which can be described as:

$${η}_{side , a} = {ϕ}_{s} - {ϕ}_{l} - {ϕ}_{eq , side , a} - {R}_{pass , a} {i}_{total , a} \qquad ( 4 )$$

where φ_{eq,side,α} is the equilibrium potential of the passivation layer formation on the anode.

### Electrode Kinetics on the Cathode

On the cathode, the layered structures of NMC active material undergo a two-phase transition to form a passivation layer of rock-salt structures at the electrode surface. At the same time, the bulk remains intact. The total current density combines lithium ions intercalation in all active materials, i.e., NMC and LMO, and the side reaction current density of passivation layer formation on the cathode surface. The passivation layer formation consumes lithium ions. Therefore, the total current density on the cathode can be expressed as:

$${i}_{total , c} = \sum {i}_{m} + {i}_{side , c} \qquad ( 5 )$$

where i_{side,c} stands for the current density of passivation layer formation on the cathode. iₘ (m=NMC or LMO) indicates the current density of lithium intercalation on the surface of NMC or LMO particles, which can be depicted by the Butler-Volmer equation:

$${i}_{m} = {k}_{m} {F ( {C}_{s} )}^{{α}_{c}} {( \frac{{c}_{l}}{{c}_{l , 0}} ( {C}_{s , max} - {C}_{s} ) )}^{{α}_{a}} ( {e}^{\frac{{α}_{a} F}{R T} {η}_{c , m}} - {e}^{- \frac{{α}_{c} F}{R T} {η}_{c , m}} ) \qquad ( 6 )$$

where, kₘ (m=NMC or LMO) is the reaction rate constant of NMC or LMO electrode, Cₛ is the solid phase lithium ion concentration at the particle surface, Cₗ is the lithium ion concentration in the electrolyte, C_{l,0} is the initial value of the concentration of the lithium ions in the electrolyte, which is equal to 1000 mol m⁻³ in this model, C_{s,max} is the maximum solid-phase lithium ion concentration, and η_{c,m} represents the overpotential of the lithium ion intercalation on the cathode, given as:

$${η}_{c , m} = {ϕ}_{s} - {ϕ}_{l} - {ϕ}_{eq , m} - {R}_{pass , c} {i}_{total , c} \qquad ( 7 )$$

where φe_{q,m} (m=NMC or LMO) is the equilibrium potential of NMC or LMO electrode, and R_{pass,c} is the resistance of the passivation layer on the cathode particles.

The aging of cathode material mainly results from a passivation layer formed on the surface of NMC particles, and LMO particles tend to be stable under the normal operating range in the NMC-LMO electrode. In this analysis, the thickness of the passivation layer on LMO particles is assumed to be zero. The reaction of passivation layer formation on the NMC particles is assumed to be nonreversible, which can be described with:

$${i}_{side , c} = - {i}_{side , c , 0} {e}^{\frac{- {α}_{c , side , c} {n}_{side , c} F}{R T} {η}_{side , c}} \qquad ( 8 )$$

where i_{side,c} is the current density of the side reaction for the formation of the cathode passivation layer, i_{side,c,0} is the exchange current density of the formation of the cathode passivation layer. η_{side,c} is the number of electrons involved to form one mole of the passivation layer on the cathode. η_{side,c} is the overpotential of the passivation layer formation on the cathode, which can be described as:

$${η}_{side , c} = {ϕ}_{s} - {ϕ}_{l} - {ϕ}_{eq , side , c} - {R}_{p a s s , c} {i}_{total , c} \qquad ( 9 )$$

where φ_{eq,side,c} is the equilibrium potential of the passivation layer formation on the cathode. R_{pass,c} is the resistance of the passivation layer on the cathode.

### Degradation Modes

Previous studies suggest categorizing the effect of the phase transition of NMC particles into three degradation modes: loss of lithium inventory, loss of active materials, and increase of resistance. In this case, the dead lithium accumulation at the lithium metal anode impedes the transportation of lithium ions, which increase the resistance on the half cell anode. Meanwhile, the phase transformation from layer structure to rock salt phase on the surface of the NMC particles hinder lithium ion transportation, resulting in resistance increase, loss of active material and loss of recyclable lithium on the cathode. The loss of total lithium inventory inside the battery cell is ignored since the electrode has been relithiated, and the lithium metal anode can be considered an infinite lithium source. Thus, four degradation modes are considered in this model: resistance increase on the anode, resistance increase on the cathode, loss of active material and loss of recyclable lithium.

On the anode, the passivation layer mentioned above would lead to a resistance increase, which can be given as:

$${R}_{pass , a} = \frac{{L}_{p ass , a}}{{κ}_{p ass , a}} \qquad ( 10 )$$

where R_{pass,α} indicates the resistance of the anode passivation layer. κ_{pass,α} indicates the conductivity of the anode passivation layer. L_{pass,α} represents the thickness of the passivation layer on the anode. Similar to the formation of the SEI layer, the growth of the passivation layer is given as:

$${L}_{p a s s , a} = {L}_{pass , a , 0} + \frac{1}{{n}_{side , a} F} {\int }_{0}^{{t}_{o p}} {Ω}_{p a s s , a} {i}_{side , a} d t \qquad ( 11 )$$

where Ω_{pass,α} stands for the molar volume of the anode passivation layer. top indicates the operating time of the battery. L_{pass,α,0} is the initial thickness of the anode passivation layer.

On the cathode, the passivation layer resists the diffusion of lithium ions during intercalation/deintercalation, leading to the loss of recyclable lithium. Therefore, the diffusion coefficient of the passivation layer is smaller than the non-degraded NMC. In this analysis, an effective diffusion coefficient of the directly recycled NMC particles is derived to compute the mass balance of the cathode for ease of computation. According to Ficks' law, the flux of lithium ions inside the recycled NMC particles ( [symbol] ) can be described using the following equations:

$$\vec{N} = - {D}_{s , core} \frac{{dC}_{core}}{d r} = - {D}_{s , pass} \frac{{dC}_{pass}}{d r} = - {D}_{s , eff} \frac{{dC}_{particle}}{d r} \qquad ( 12 )$$

where D_{s,core} and D_{s,pass} are the diffusion coefficients of non-degraded layered NMC and the passivation layer, respectively. D_{s,eff} is the effective diffusion coefficient of the recycled NMC particles. C_{core} and Cₚₐₛₛ is the solid phase concentration of the non-degraded active material and the passivation layer of the recycled NMC particles, respectively. C_{particle} is the solid phase concentration inside the recycled NMC particles. For the ease of computation, the concentration gradient can be estimated using the following equations:

$$\frac{d {C}_{core}}{d r} = \frac{Δ {C}_{core}}{{R}_{p , NMC} - {L}_{p ass , c}} \qquad ( 13 )$$

$$\frac{d {C}_{pass}}{d r} = \frac{Δ {C}_{pass}}{{L}_{pass , c}} \qquad ( 14 )$$

$$\frac{d {C}_{p a r t i c l e}}{d r} = \frac{Δ {C}_{c o r e} + Δ {C}_{p a s s}}{{R}_{p , NMC}} \qquad ( 15 )$$

where

$$\frac{dC}{dr}$$

represents the concentration gradient over the radial direction. ΔC_{core} indicates the concentration difference between the center and the surface of the non-degraded active material, ΔCₚₐₛₛ represents the concentration difference between the inner and outer surface of the passivation layer, R_{p,NMC} stands for the particle size of NMC, L_{pass,c} is the thickness of the passivation layer on the cathode, similar to the formation of the SEI layer, it yields:

$${L}_{pass , c} = {L}_{pass , c , 0} + \frac{I}{{n}_{s i d e} F} {\int }_{0}^{{t}_{o p}} {Ω}_{p a s s , c} {i}_{side , c} d t \qquad ( 16 )$$

where Ω_{pass,c} stands for the molar volume of the passivation layer on the cathode. L_{pass,c,0} is the initial thickness of the passivation layer on the cathode.

Substitute equations 13, 14 and 15 into 12, the effective diffusion coefficient of the recycled NMC particles can be derived as:

$${D}_{s , eff} = \frac{{D}_{s , core} {D}_{s , pass} {R}_{p , NMC}}{{D}_{s , pass} ( {R}_{p , NMC} - {L}_{pass , c} ) + {D}_{s , core} {L}_{pass , c}} \qquad ( 17 )$$

Meanwhile, the passivation layer would serve as a lithium ion conductor with resistance, leading to a resistance increase on the cathode, which can be given as:

$${R}_{pass , c} = \frac{{L}_{pass , c}}{{κ}_{pass , c}} \qquad ( 18 )$$

where K_{pass,c} is the conductivity of the passivation layer on the cathode.

The passivation layer is considered unable to store lithium and thus provides no capacity. Then the loss of active material on the cathode can be described as:

$${ε}_{s , rNMC} = {ε}_{s , rNMC , 0} ( 1 - {( \frac{{L}_{pass , c}}{{R}_{p , NMC}} )}^{3} ) \qquad ( 19 )$$

where ε_{s,rNMC} indicates the volume fraction of the recycled NMC active material, ε_{s,rNMC,0} stands for the initial value of the volume fraction of the recycled NMC active material. R_{p,NMC} is the particle size of NMC.

### Governing Equations and Parameters

The full cell anode is a porous electrode, while the half cell anode is defined as a surface of infinite lithium source. Therefore, the boundary conditions of the full cell and half cell are different. The lithium ion flux flowing outside the system (at x=0) is defined as zero for the full cell. In contrast, flux continuity is defined at x=0 for the half cell. The governing equations, including the mass and charge balance of the electrode and electrolyte, together with the boundary conditions of the full cell and the half cell, were summarized in Table 1.

TABLE 1
Governing equations and boundary conditions

| Governing equations | Boundary conditions-full cell | Boundary conditions-half cell |
|---|---|---|
| Mass balance of the electrode | $\frac{\partial {C}_{s}}{\partial r} {\vert}_{r = 0} = 0$ | $\frac{\partial {C}_{s}}{\partial r} {\vert}_{r = 0} = 0$ |
| $\frac{\partial {C}_{s}}{\partial t} = \frac{{D}_{s , eff}}{{r}^{2}} \frac{\partial }{\partial r} ( {r}^{2} \frac{\partial {C}_{s}}{\partial r} )$ | ${- {D}_{s} \frac{\partial {C}_{s}}{\partial r} \vert}_{r = {r}_{p}} = \frac{{i}_{total}}{F}$ | ${- {D}_{s} \frac{\partial {C}_{s}}{\partial r} \vert}_{r = {R}_{p}} = \frac{{i}_{total , c}}{F}$ |
| Mass balance of the electrolyte | $\frac{\partial {C}_{l}}{\partial x} {\vert}_{x = 0} = 0$ | $- {D}_{l} {ε}_{l}^{1.5} \frac{\partial {C}_{l}}{\partial x} {\vert}_{x = 0} = ( \frac{1 - {t}_{+}}{F} ) {i}_{total , a}$ |
| ${ε}_{l} \frac{\partial {C}_{l}}{\partial t} = \frac{\partial }{\partial x} ( {D}_{l} {ε}_{l}^{1.5} \frac{\partial {C}_{l}}{\partial x} ) + {a}_{s} ( \frac{1 - {t}_{+}}{F} ) {i}_{total}$ | ${\frac{\partial {C}_{l}}{\partial x} \vert}_{x = {L}_{n e g} + {L}_{s e p} + {L}_{p o s}} = 0$ | ${\frac{\partial {C}_{l}}{\partial x} \vert}_{x = {L}_{s e p} + {L}_{p o s}} = 0$ |
| ${a}_{s} = \frac{3 {ε}_{s}}{{R}_{p}}$ | | |
| Charge balance of the electrode | ${ϕ}_{s} {\vert}_{x = 0} = 0$ | ${ϕ}_{s} {\vert}_{x = 0} = 0$ |
| ${σε}_{s}^{1.5} \frac{{\partial }^{2} {ϕ}_{s}}{\partial {x}^{2}} = {a}_{s} {i}_{total}$ | ${σ {ε}_{s}^{1.5} \frac{\partial {ϕ}_{s}}{\partial x} \vert}_{x = {L}_{n e g} + {L}_{s e p} + {L}_{p o s}} = {i}_{app}$ | ${σ {ε}_{s}^{1.5} \frac{\partial {ϕ}_{s}}{\partial x} \vert}_{x = {L}_{s e p} + {L}_{p o s}} = {i}_{app}$ |
| Charge balance of electrolyte | $\frac{\partial {ϕ}_{l}}{\partial x} {\vert}_{x = 0} = 0$ | ${κ}_{l} {ε}_{l}^{1.5} \frac{\partial {ϕ}_{l}}{\partial x} + {κ}_{D} {ε}_{l}^{1.5} \frac{\partial ln {C}_{l}}{\partial x} {\vert}_{x = 0} = - {i}_{total , a}$ |
| $\frac{\partial }{\partial x} ( {κ}_{l} {ε}_{l}^{1.5} \frac{\partial {ϕ}_{l}}{\partial x} ) + \frac{\partial }{\partial x} ( {κ}_{D} {ε}_{l}^{1.5} \frac{\partial ln {C}_{l}}{\partial x} ) + {a}_{s} {i}_{total} = 0$ | ${\frac{\partial {ϕ}_{l}}{\partial x} \vert}_{x = {L}_{n e g} + {L}_{s e p} + {L}_{p o s}} = 0$ | ${\frac{\partial {ϕ}_{l}}{\partial x} \vert}_{x = {L}_{s e p} + {L}_{p o s}} = 0$ |
| ${κ}_{D} = \frac{2 R T {κ}_{l}}{F} ( 1 - {t}^{+} )$ | | |

TABLE 2
Modeling parameters

| | Value/ | | | |
|---|---|---|---|---|
| Symbol | Expression | Unit | Description | Source |
| C_{l, 0} | 1,000 | mol m⁻³ | Initial concentration | Jung S., (2014) 264, 184-194. |
| | | | of lithium ions in the | |
| | | | electrolyte | |
| C_{s, LMO, max} | 3.5E⁵ | mol m⁻³ | Maximum solid phase | Fitted based on full cell |
| | | | concentration of LMO | voltage curves |
| C_{s, NMC, max} | 4.95E⁴ | mol m⁻³ | Maximum solid phase | Das, M. K. et al., (2018). |
| | | | concentration of NMC | Porous Media Applications; |
| | | | | electrochemical systems, pp. |
| | | | | 93-122. |
| Dₚₐₛₛ | 2.5E⁻¹⁷ | m² s⁻¹ | Diffusion coefficient | Fitted based on the rate |
| | | | of the passivation | capability |
| | | | layer | |
| D_{s, neg, f} | 9E⁻¹³ | m² s⁻¹ | Diffusion coefficient | Fitted based on full cell |
| | | | of graphite anode for | voltage curves |
| | | | the full cell | |
| D_{s, LMO} | 2.5E⁻¹³ | m² s⁻¹ | Solid phase diffusion | Jung S., (2014) 264, 184-194. |
| | | | coefficient of LMO | |
| φ_{eq, side, a} | 0.4 | V | Equilibrium potential | Assume to be the same as SEI |
| | | | of anode passivation | formation |
| | | | layer | |
| φ_{eq, side, c} | 0.4 | V | Equilibrium potential | Assume to be the same as the |
| | | | of the cathode | anode |
| | | | passivation layer | |
| φ_{eq, pNMC} | FIG. 7 | V | Pristine NMC | Das, M. K. et al., (2018). |
| | | | equilibrium potential | Porous Media Applications; |
| | | | | electrochemical systems, pp. |
| | | | | 93-122. |
| φ_{eq, rNMC} | FIG. 7 | V | Recycled NMC | As described herein. |
| | | | equilibrium potential | |
| φ_{eq, LMO} | 0.225 − | V | LMO equilibrium | Petit et al., (2020), J. Power |
| | 0.392x | | potential | Sources 479, 228766 |
| | + 2.2tanh(−1 [symbol] | | | |
| | − 0.994)) | | | |
| | + 1.9tanh(−2 [symbol] | | | |
| | − 1.04)) | | | |
| | + 0.181sech(2 [symbol] | | | |
| | − 0.397)) | | | |
| | − 0.175sech(2 [symbol] | | | |
| | − 0.399)) | | | |
| | + 0.0164sech( [symbol] | | | |
| | − 0.567)) | | | |
| | + 0.33sech(48 [symbol] | | | |
| | − 1)) | | | |
| ε_{l, neg, f} | 0.28 | 1 | Porosity of the | Jung S., (2014) 264, 184-194. |
| | | | negative electrode for | |
| | | | full cell simulation | |
| ε_{l, sep} | 0.37 | 1 | Porosity of the | Jung S., (2014) 264, 184-194. |
| | | | separator | |
| ε_{s, LMO} | 0.155 | 1 | Volume fraction of | Derived from the 7:3 weight |
| | | | LMO particles | ratio of NMC and LMO |
| ε_{s, NMC} | 0.345 | 1 | Volume fraction of | Derived from the 7:3 weight |
| | | | NMC particles | ratio of NMC and LMO |
| I_{1C} | 4.46E⁻⁴ | A | Half cell 1C current | Measured |
| i_{side, 0, c} | 4.87E⁻⁴ | A m⁻² | Exchange current | Fitted based on the aged half |
| | | | density of cathode | cell voltage curves |
| | | | passivation layer | |
| | | | formation | |
| i_{side, 0, a} | 1.05E⁻⁴ | A m⁻² | Exchange current | Fitted based on the aged half |
| | | | density of anode | cell voltage curves |
| | | | passivation layer | |
| | | | formation | |
| i_{a, 0} | 20 | A m⁻² | Reference exchange | Assumed |
| | | | current density Li | |
| | | | metal | |
| k_{neg, f} | 8E⁻¹⁰ | m s⁻¹ | Reaction rate | Fitted based on full cell |
| | | | coefficient of graphite | voltage curves |
| | | | anode for full cell | |
| | | | simulation | |
| k_{pos, LMO} | 8E⁻¹⁰ | m s⁻¹ | Reaction rate | Fitted based on full cell |
| | | | coefficient of LMO | voltage curves |
| k_{pos, NMC} | 8E⁻¹⁰ | m s⁻¹ | Reaction rate | Fitted based on full cell |
| | | | coefficient of NMC | voltage curves |
| L_{pass, a, 0} | 1E⁻⁹ | m | Initial thickness of the | Assumed |
| | | | anode passivation | |
| | | | layer for half cell | |
| L_{pass, c, 0, h} | 1.7E⁻⁸ | m | Initial thickness of the | Fitted based on the fresh half |
| | | | cathode passivation | cell voltage curves and rate |
| | | | layer for half cell | capability |
| L_{neg, f} | 5E⁻⁵ | m | Length of negative | Jung S., (2014) 264, 184-194. |
| | | | electrode for full cell | |
| | | | simulation | |
| L_{pos, f} | 5.5E⁻⁵ | m | Length of positive | Jung S., (2014) 264, 184-194. |
| | | | electrode for full cell | |
| | | | simulation | |
| L_{pos, h} | 7.5E⁻⁵ | m | Length of positive | Measured |
| | | | electrode for half cell | |
| | | | simulation | |
| L_{sep, f} | 2.5E⁻⁵ | m | Length of separator | Jung S., (2014) 264, 184-194. |
| | | | for full cell simulation | |
| L_{sep, h} | 2E⁻⁵ | m | Length of separator | Measured |
| | | | for half cell | |
| | | | simulation | |
| R_{p. LMO, f} | 7.5E⁻⁶ | m | Particle size of LMO | Jung S., (2014) 264, 184-194. |
| | | | for full cell simulation | |
| R_{p, NMC, f} | 4.5E⁻⁶ | m | Particle size of NMC | Jung S., (2014) 264, 184-194. |
| | | | for full cell simulation | |
| R_{p, LMO, h} | 1E⁻⁵ | m | Particle size of LMO | Measured |
| | | | for half cell | |
| | | | simulation | |
| R_{p, NMC, h} | 2E⁻⁵ | m | Particle size of NMC | Measured |
| | | | for half cell | |
| | | | simulation | |
| κ_{pass, a} | 2.85E⁻⁶ | S m⁻¹ | Electronic | Fitted based on the aged half |
| | | | conductivity of anode | cell voltage curves |
| | | | passivation layer | |
| σ_{LMO} | 3.8 | S m⁻¹ | Electrical conductivity | Dai, M. et al. (2018), Adv. |
| | | | of LMO | Theory, Simul. 1(10), |
| | | | | 1800023. |
| κ_{pass, c} | 7.5E⁻⁷ | S m⁻¹ | Electronic | Fitted based on the aged half |
| | | | conductivity of | cell voltage curves |
| | | | cathode passivation | |
| | | | layer | |
| T | 298 | K | Temperature | Measured for half cell for full |
| | | | | cell, |
| | | | | Jung S., (2014) 264, 184-194. |
| Ω_{pass, a} | 2E⁻⁶ | m³ mol⁻¹ | Molar volume of | Su, B. et al. (2022), J. Energy |
| | | | anode passivation | Storage 49, 104105. |
| | | | layer | |
| Ω_{pass, c} | 2E⁻⁶ | m³ mol⁻¹ | Molar volume of | Assumed to be the same as |
| | | | cathode passivation | the anode |
| | | | layer | |

[symbol]

indicates data missing or illegible when filed

Due to the structural reconstruction of NMC, several properties of the directly recycled electrode are different from those of the pristine electrode. First, studies have found that equilibrium voltage (φ_{eq}) of the electrode is highly dependent on the aging state of the batteries, implying that the φ_{eq} of the pristine and relithiated NMC electrode can be different. However, no specific studies have quantified the relationship between φ_{eq} and the aging state of the NMC-LMO electrode. As shown in equation 7, the overpotential of the directly recycled electrode is dependent on the φ_{eq} and the current density. Therefore, to accurately capture the voltage behavior of the directly recycled electrode, the φ_{eq} of the recycled NMC material is modified by fitting the simulated voltage behavior to the experimental data under the 0.5° C. test mentioned in this example. The following assumptions are made to fit the φ_{eq} of the recycled electrode: 1) Since the LMO electrode is relatively stable with the presence of NMC, the φ_{eq} of the LMO electrode remains unchanged. 2) Since the microstructural changes only happened on the passivation layer on the surface of the electrode, the φ_{eq} of NMC remains unchanged in the bulk of NMC. Based on the above assumptions, the φ_{eq} of the recycled NMC is defined as a piecewise function in this analysis. When the stoichiometry is lower than 0.7, i.e., in bulk NMC, the Deg is the same as pristine NMC, the value of which can be found in our previous publication. On the contrary, when the stoichiometry is larger than 0.7, the term φ_{eq} of the recycled NMC is fitted as an unknown parameter using in equation 7 by matching the simulated and experimental data of the 0.5C discharge voltage curve (shown in FIG. 6A). FIG. 4 shows the fitted Peg of the recycled NMC electrode applied in this model compared with that of the pristine NMC electrode. The quality improvement of simulation results caused by the φ_{eq} modification will be discussed in Section 3.1.

Except for equilibrium potential, the main difference between the pristine and directly recycled NMC is the passivation layer's initial thickness. The initial thickness of the rock salt layer is assumed to be 0 nm for the pristine cell and fitted as 17 nm for the recycled cell. In addition, several properties of the active material will change due to the growth of passivation layer thickness, such as the diffusion coefficient of the particles (equation 17), volume fraction of the NMC active material (equation 19), as well as the resistance of the passivation layer (equation 18). The initial thickness of the passivation layer on the anode depends on the chemistry of the electrolyte, which can be anywhere from less than 1 nm to 10 nm. In this example, the initial thickness of the anode passivation layer is assumed to be 1 nm. The parameters applied in this analysis are summarized in Table 2, including the physical properties of electrodes and the electrolyte, side reaction factors, and cell dimensions. Most of the physical properties of the directly recycled NMC materials are assumed to be the same as those of the pristine materials. Other parameters, such as cell dimensions, particle sizes, and volume fractions, are defined based on the experimental measurements.

### Results

### Model Validation

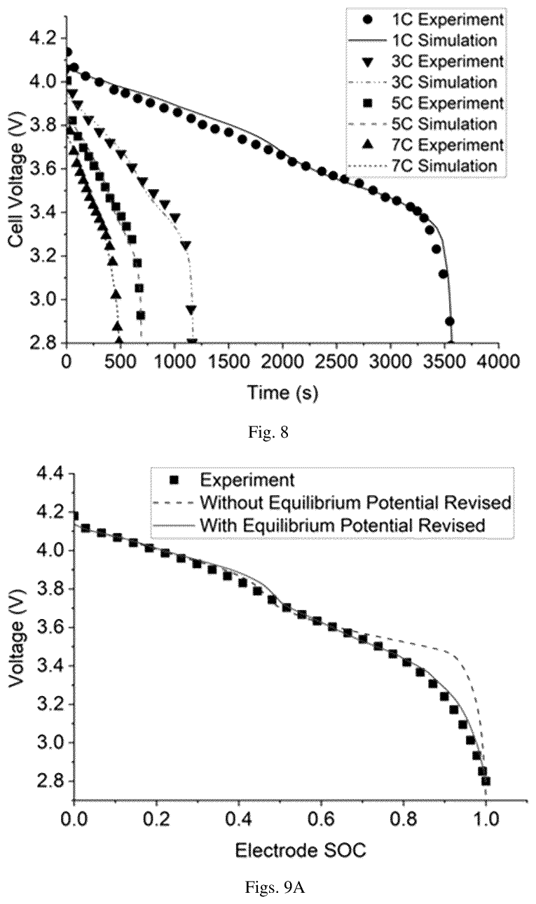

To examine the capability of the model to capture the electrochemical performance of the NMC-LMO electrode, the voltage behavior at 1C, 3C, 5C and 7C current rates of a pristine NMC-LMO graphite full cell are simulated and validated with experimental data. The following steps are used for the simulations: (1) Charge at a constant current of 0.5C until reaching the cutoff voltage of 4.2V; (2) Charge at a constant voltage of 4.2V until reaching the cutoff current of 0.02C; (3) Discharge at a constant current with the desired rate (1C, 3C, 5C or 7C) until reaching the cutoff voltage of 2.8 V. At Step (3), the 1C, 3C, 5C and 7C discharge curve results are computed. As shown in FIG. 8, the simulated discharge curves of the full cell voltage match well with the experimental data, proving that the simulation parameters regarding NMC and LMO electrochemical properties are reasonable.

To verify the modified deg, the voltage behavior of the directly recycled electrode half cell under a 0.5C current rate with and without φ_{eq} modification is computed and compared with experimental data. The following steps are used for the half cell voltage behavior simulation: (1) Charge at a constant current of 0.5C until the cutoff voltage of 4.2V; (2) Charge at a constant voltage of 4.2V until the cutoff current of 0.02C; (3) Discharge at a 0.5C constant current until the cutoff voltage of 2.8 V; The results of discharge curves are given from step (3). As shown in FIG. 5a, there is a distinct gap between the 0.5C voltage curves of the simulation result without φ_{eq} modification and the experimental data, especially when the electrode is highly lithiated and the cell voltage is low. On the contrary, the simulated voltage curve under 0.5C after Peg modification agrees well with the experiment. This proves the necessity of the φ_{eq} modification.

To examine the electrode performance under different current rates, the rate capability of the directly recycled NMC-LMO half-cell is simulated and validated with experimental data. The following steps are used for the rate capability simulation: (1) Charge at a constant current of 0.5C until the cutoff voltage of 4.2V; (2) Charge at a constant voltage of 4.2V until the cutoff current of 0.02C; (3) Discharge at a constant current with the desired rate (0.1C, 0.2C, 0.5C, 1C, 2C, 5C) until the cutoff voltage of 2.7V; The above-mentioned steps are repeated five times for each current density. The results of rate capability are provided in step (3).

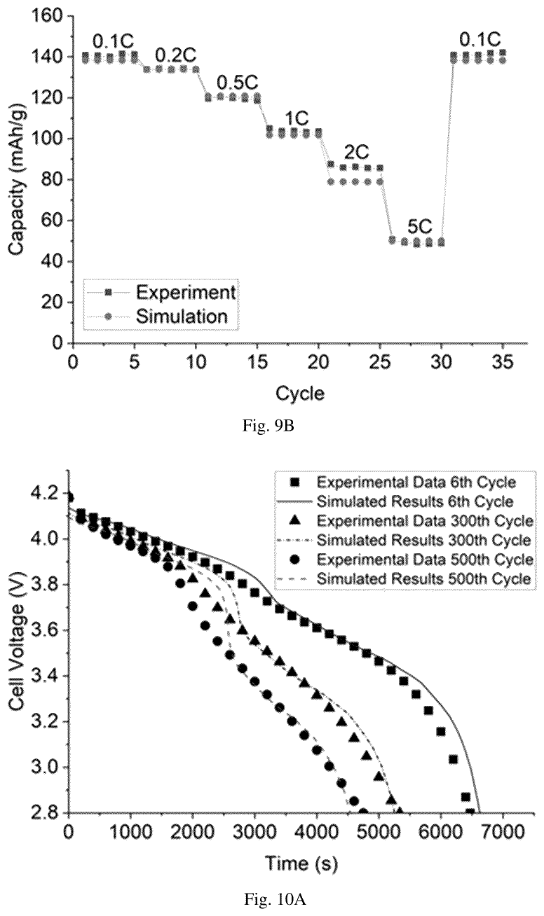

FIG. 9B displays simulated and experimental results of the rate capability. It is evident that the capacity achieved by the end of discharge is highly dependent on the C-rate, decreasing significantly from 138.23 mAh g-1 to 50.05 mAh g-1 as the C-rate rises from 0.1C to 5C. This performance is notably lower than that of pristine NMC-LMO material reported, where capacity utilization exceeds 85% at 5C. The trend of rate capability worsening over aging is also seen in other literature, and it can be explained by the worsening diffusion property and the increase of resistance. It can be observed that the simulation results match well with the experimental data except for the results at 2C current density. One possible reason is that this example does not consider the interactions between NMC and LMO particles in the mixed cathode since their interplay remains unclear. Another reason is the φ_{eq} change of LMO due to microstructural changes is ignored due to the lack of relative research. Moreover, the existing of metallic and nonmetallic impurities generated from the direct recycling process may electrochemical performance change of the electrode leading to the gap between experimental data and simulation results.

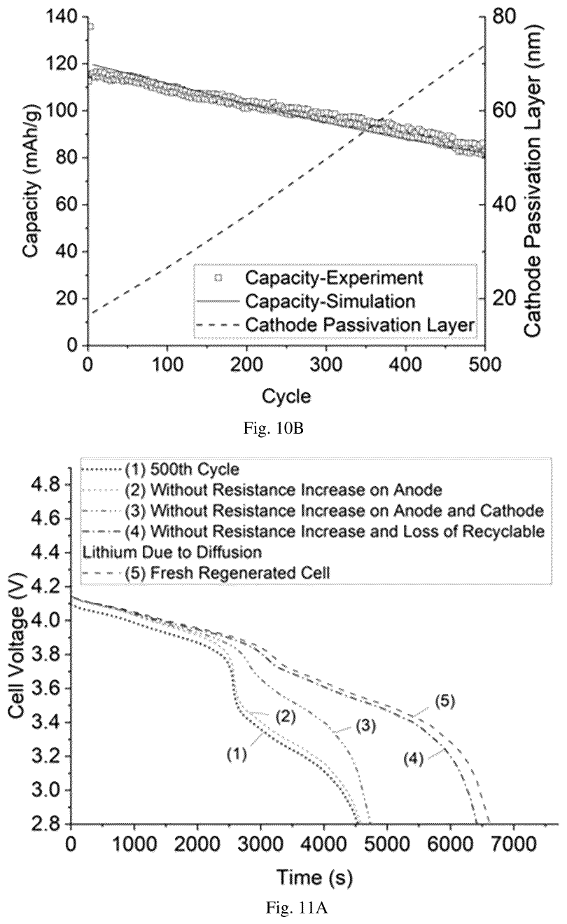

To validate the modeling results of the cycling capacity loss behavior, the simulated discharge curves and remaining capacities regarding cycle numbers were compared with the experimental data of the directly recycled NMC-LMO electrode half cell cycling performance mentioned. For this simulation, the following steps are used: (1) Charge at a constant current rate of 0.5C until the cutoff voltage of 4.2V; (2) Charge at a constant voltage of 4.2V until the cutoff current of 0.02C; (3) Discharge at a constant current of 0.5C until the cutoff voltage of 2.8V. The above steps were repeated for 500 times. FIG. 10A shows the simulated discharge curve of the cell voltage for the 6th (the first cycle after the formation cycles), 300th, and 500th cycles. As shown in FIG. 10A, after 500 cycles at 0.5C, the remaining capacity dropped to 70.12% of its original capacity. A change in the trend of the voltage curve is observed at around 50-70% state of charge (SOC) in both the simulation and experimental results, which might result from a ratio change between LMO and NMC due to the loss of NMC active materials. A similar trend of voltage behavior changes from pristine electrodes to aged electrodes has been observed in previous publications. However, a difference in the voltage behavior is observed between the experimental data and the simulated results at this SOC range. Apart from the ignorance of particle interactions, impurity of the electrode materials and the LMO microstructure change mentioned above, these discrepancies may also come from the continuous Peg change of the recycled NMC during the cycling test which is overlooked due to the lack of experimental data. FIG. 10B shows the capacity loss and the cathode passivation layer thickness growth of the recycled NMC-LMO half cell with respect to the cycle number. It can be observed that the capacity loss regarding the cycle numbers matches the experimental data reasonably well. Meanwhile, the passivation layer on NMC particles is proportional to the amount of capacity loss, increasing from 17 to 74 nm after 500 cycles, which is reasonable since it is reported that the passivation layer thickness of an aged NMC coin cell at 77% capacity retention ranges from 20~200 nm.

### The Effect of Degradation Modes on Battery Capacity and Power Loss

To study the effect of each degradation mode on battery capacity and power loss, the remaining capacities of the aged cell after 500 cycles are computed at 0.5C discharge rate under the voltage range of 2.8-4.2V with the following adjustments: (1) With all the degradation modes mentioned coupled in the model; (2) With cathode resistance increase, diffusion property changes of the directly recycled NMC particles and loss of active material coupled in the model (L_{pass,α}=L_{pass,α,0}); (3) With diffusion property change of the directly recycled NMC particles and loss of active material coupled in the model (L_{pass,α}=L_{pass,α,0}, L_{pass,c}=L_{pass,c,0}); (4) With loss of active material only coupled in the model (L_{pass,α}=L_{pass,α,0}, L_{pass,c}=L_{pass,c,0}, D_{s,eff}=D_{s,core}); (5) Without any degradation modes coupled in the model (L_{pass,α}=L_{pass,α,0}, L_{pass,c}=L_{pass,c,0}, D_{s,eff}=D_{s,core}, ε_{s,rNMC}=ε_{s,NMC,0}). The simulated charging/discharging process is the same as the 0.5C cycling test mentioned. All the simulation results are shown in FIG. 11A. FIG. 11B summarizes the estimated percentages of capacity and power loss caused by each degradation mode. Specifically, the difference between line (1) and line (2) in FIG. 11A indicates the effect of anode resistance increase in FIG. 11B; The difference between line (2) and line (3) in FIG. 11A quantifies the effect of cathode resistance increase in FIG. 11B; The difference between line (3) and line (4) in FIG. 11A measures the effect of the loss of recyclable lithium in FIG. 11B; The difference between line (4) and line (5) in FIG. 11A measures the effect of the loss of active materials in FIG. 11B. The distance between the intersections of each line with the X-axis in FIG. 11A quantifies the capacity loss, whereas the area between each line corresponds to the power loss. Based on this analysis, the loss of recyclable lithium dominates the capacity and power loss of the directly recycled NMC-LMO hybrid electrode, accounting for 78.9% and 71.3% of the total capacity and power loss, respectively. The second dominant degradation mode is the resistance increase on the cathode, which takes up 9.5% of the total capacity fade and 15.6% of the total power fade, respectively. The dominant degradation mode found in this analysis agrees with several previous publications. However, it needs to be noted that the dominant degradation factors depend highly on the operating conditions. If the operating temperature, SOC range or applied current are changed, other degradation modes, such as loss of active material, might be more noticeable.

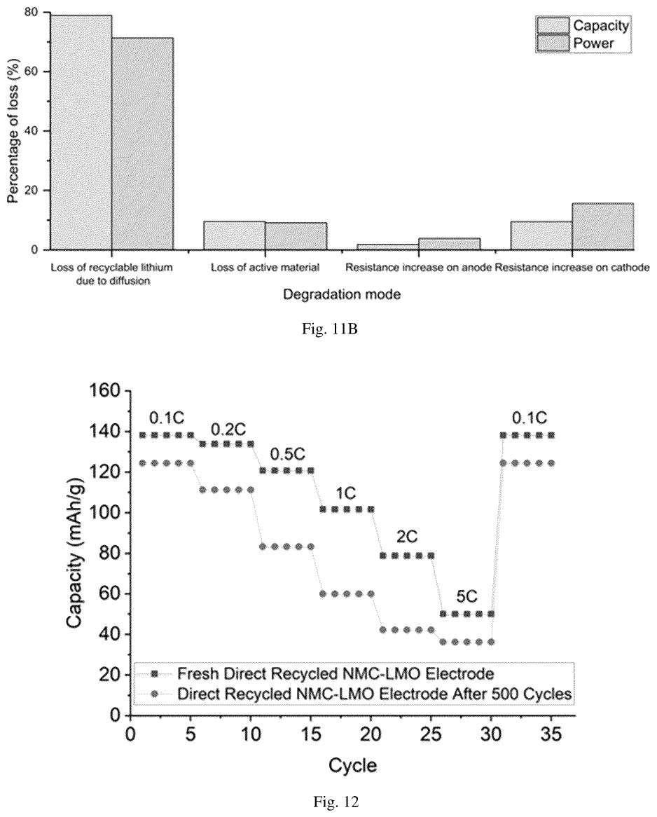

As discussed above, the dominant and second dominant degradation modes of the directly recycled electrode are the diffusion property change and the resistance increase on the cathode, which would cause an increase of the diffusion and ohmic overpotential, respectively. These overpotentials would limit the amount of lithium inventory transferred under the same voltage window, i.e., from 4.2V to 2.8V. As the overpotentials are highly dependent on the applied current density, the amount of lithium ions that are “trapped” inside the active material will be less under a low current. Therefore, the loss of recyclable lithium due to lithium mobility change and resistance increase affects capacity loss under higher applied currents. FIG. 12 shows the computed rate capability of the recycled half cell after 500 cycles. As shown in FIG. 12, the recycled half cell after 500 cycles of aging can still deliver 126 mAh/g of achievable capacity, around 90% of its original capacity, when tested under a low current rate of 0.1C. By contrast, only 64% of the original capacity is achievable after the 500 cycles if tested under the 1C current rate. Evidence of such a trend that the worsened lithium mobility is more influential on the degradation behavior at higher current density is provided in previous publications. The results demonstrate that directly recycled cathode materials, when processed appropriately, can maintain high-quality performance comparable to pristine materials for applications requiring low current density, such as stationary energy storage systems. This is particularly crucial for the feasibility of applications of the directly recycled lithium-ion batteries. According to the SEIA report, the US manufacturing capacity for all lithium ion battery applications is currently at 60 GWh. In comparison, the US demand for battery energy storage systems may increase to 119 GWh by 2030. This huge gap can be filled by applying the directly recycled electrode generated from spent LIBs energy storage systems, which will not only release the pressure of market demand but also avoid the pollution-intensive battery end-of-life treatment process of the upcoming retired batteries from electric vehicles.

However, it can be observed from FIG. 12 that the remaining deliverable capacity dramatically drops after 500 cycles if the tested current is larger than 1C. Solid electrolytes may have great potential to compensate for the high current deliverable capacity of the directly recycled electrode. In solid electrolytes, electrochemical cycling forms the rock salt phase that is found to be dispersed into the bulk of the NMC particle instead of the electrode/electrolyte interface only. Unlike the liquid electrolyte, the dispersed rock salt phase will not perform as a layer with poor diffusion properties. Instead, the local stress in the rock salt phase can squeeze lithium ions out of the rock salt phase into the adjacent layered phases and further out of the NMC particle, allowing the rock salt phase to be electrochemically active. Therefore, diffusion-related overpotential can be mitigated, and the behavior of high current capacity will improve.

From the above description of the invention, those skilled in the art will perceive improvements, changes and modifications. Such improvements, changes and modifications within the skill of the art are intended to be covered by the appended claims. All references, publications, and patents cited in the present application are herein incorporated by reference in their entirety.

Having described the invention, we claim:

1. A computer-implemented method for predicting the remaining useful life of a directly recycled battery system, the computer implemented method comprising:
receiving data pertaining to components and configuration of the directly recycled battery system;
receiving data pertaining to governing equations that describe electrochemical performance of the directly recycled battery system;
receiving data pertaining degradation mechanisms affecting the battery's performance over time;
defining and adjusting electrochemical model parameters based on the received data to reflect the battery electrochemical performance;
calibrating the electrochemical model by comparing its predictions with experimental and historical data from real-world batteries with directly recycled electrodes;
performing predictive analytics and uncertainty quantification by using the calibrated electrochemical model to simulate and analyze the remaining useful life of the batteries under different operating conditions; and
transmitting the predicted remaining useful life of the directly recycled battery system to a presentation on a use interface of a computing device or to be further processed by another computer device.

2. The computer-implemented method of claim 1, wherein the directly recycled battery system includes an anode material selected from lithium metal for half-cell and graphite for full-cell, a cathode material comprising a directly recycled mixed electrode, and an electrolyte comprising a lithium-ion conducting electrolyte.

3. The computer-implemented method of claim 1, wherein the governing equations for the battery system include mass balance equations, charge balance equations, and electrochemical kinetics equations.

4. The computer-implemented method of claim 3, wherein the electrochemical kinetics equations include a modified Butler-Volmer equation that models a first electrode intercalation, a second electrode intercalation, and side reactions occurring within the battery system.

5. The computer-implemented method of claim 1, wherein degradation mechanisms for the battery system include layer-rock salt phase transformations in NMC, resulting in anode passivation layer formation and resistance growth, as well as Mn dissolution in LMO, which is mitigated by the presence of NMC.

6. The computer-implemented method of claim 5, wherein the impact of layer-rock salt phase transformations in NMC on degradation modes include the loss of active material, the loss of lithium inventory, resistance growth, and changes in thermodynamic properties.

7. The computer-implemented method of claim 5, wherein a machine learning model is utilized to predict the impact of various degradation mechanisms on the capacity loss behaviors of the directly recycled battery system.

8. The computer-implemented method of claim 1, wherein the governing equations incorporated with degradation mechanisms are solved numerically using finite element analysis to simulate the electrochemical performance of the directly recycled battery system.

9. The computer-implemented method of claim 1, wherein the adjusted electrochemical model parameters include aging-induced changes in material properties, equilibrium potential changes, initial passivation layer thickness, degradation current density and material properties of NMC and LMO.

10. The computer-implemented method of claim 1, wherein the experimental data required for calibration of directly recycled battery materials includes voltage behavior, rate capability, and cycling loss.

11. The computer-implemented method of claim 1, wherein the calibration involves adjusting model parameters based on experimental data to enhance the accuracy of predictive analytics for the battery system.

12. The computer-implemented method of claim 1, wherein predictive analytics are used to forecast the remaining useful life based on various initial capacities of the directly recycled electrode.

13. The computer-implemented method of claim 1, wherein uncertainty quantification involves analyzing the impact of voltage range, applied current, and operating temperature on the remaining useful life of the batteries.

14. A system for implementing the computer-implemented method of any of claim 1, comprising:
a processor configured to execute the predictive analytics;
a memory device for storing the data corresponding to remaining useful life of a recycled battery system, wherein the data includes components and configurations of recycled battery system, governing equations that describe the electrochemical performance of the battery system, and degradation mechanisms affecting the battery's performance over time; and
a user interface of a computing device for inputting operational conditions and analyzing predictive outputs and presenting the predicted remaining useful life of the directly recycled battery system.

15. The system of claim 14, further comprising a data acquisition module for collecting experimental data from aged batteries for use in a machine learning model calibration.

16. The system of claim 15, wherein the processor is further configured to receive the machine learning model from a cloud-based computing system.

17. A non-transitory computer readable medium storing a computer readable program that when executed causes a processor to:
receive by a processor data corresponding to remaining useful life of a recycled battery system, wherein the data includes components and configurations of recycled battery system, governing equations that describe the electrochemical performance of the battery system, and degradation mechanisms affecting the battery's performance over time;
define and adjust an electrochemical model parameters based on the received data to reflect the battery's electrical performance;
calibrate the electrochemical model by comparing predictions with experimental or a historical record of the data from real-world batteries with directly recycled electrodes; and
perform predictive and uncertainty quantification by using the calibrated electrochemical model to simulate and analyze the remaining of recycled battery system under different operating conditions.
